(19) United States
(12) Patent Application Publication
(10) Pub. No.: US 2019/0129555 A1
(43) Pub. Date: May 2, 2019

(54) IN-CELL CAPACITIVE TOUCH PANEL

(71) Applicant: Raydium Semiconductor Corporation, Hsinchu (TW)

(72) Inventor: Chang-Ching CHIANG, Taichung City (TW)

(21) Appl. No.: 16/176,157

(22) Filed: Oct. 31, 2018

Related U.S. Application Data
(60) Provisional application No. 62/579,194, filed on Oct. 31, 2017.

(51) Int. Cl. G06F 3/041; H01L 27/12; H01L 27/32; G06F 3/044

(52) U.S. Cl. CPC G06F 3/0412; H01L 27/1255; G06F 2203/04112; G06F 3/044; H01L 27/323

(57) ABSTRACT

An in-cell capacitive touch panel, applied to an active matrix light-emitting diode (LED) display, includes pixels and at least one touch electrode. A laminated structure of each pixel includes a substrate, a first conductive layer˜a fourth conductive layer, a transistor layer and a LED layer. The substrate is disposed at one side of the pixel. The first conductive layer is disposed above the substrate to form scan lines. The transistor layer is disposed above the substrate. The second conductive layer is disposed above the substrate to form data lines. The third conductive layer is disposed above the transistor layer. The LED layer is disposed above the third conductive layer. The fourth conductive layer is disposed above the LED layer. The at least one touch electrode is disposed in a space that the first conductive layer˜the fourth conductive layer and the LED layer are not disposed.

### BACKGROUND OF THE INVENTION

### 1. Field of the Invention

The invention relates to a touch panel; in particular, to an in-cell capacitive touch panel.

### 2. Description of the Prior Art

In recent years, organic light-emitting diode displays have been widely used in various mobile devices and micro-displays, which can be divided into active matrix organic light-emitting diode (AMOLED) displays and passive matrix organic light-emitting diode (PMOLED) displays according to different driving methods.

Compared with the passive matrix organic light-emitting diode display, the gray-scale data values for each pixel of the active matrix OLED display can be stored in its circuit, so the required driving voltage is low and suitable for high-resolution displays.

As shown in FIG. 1, the active matrix organic light-emitting diode display contains transistor circuit component area TFT and led area OLED in each pixel. The gray-level signal values of each pixel are switched on by the scanning drive SD scan line SL to turn on the corresponding transistor circuit, and is achieved by inputting the data line DL of data driver DD into the storage capacitance of the transistor circuit.

Next, please refer to FIG. 2A˜FIG. 2C. FIG. 2A˜FIG. 2C are schematic cross-sectional views showing different laminated structures of the pixel of the active matrix organic light-emitting diode display respectively.

As shown in FIG. 2A, the transistor layer TFT is disposed above the substrate SUB; the cathode electrode CE is disposed above the transistor layer TFT; the organic light-emitting diode layer OLED1 is disposed above the cathode electrode CE; and the organic light-emitting diode layer OLED1 may be red (R), green (G) or blue (B). The organic light-emitting diode is composed of an anode electrode AE and an encapsulation layer ENC arranged in this order.

As shown in FIG. 1B, the transistor layer TFT is disposed above the substrate SUB; the cathode electrode CE is disposed above the transistor layer TFT; the organic light-emitting diode layer OLED2 is disposed above the cathode electrode CE; and the organic light-emitting diode layer OLED2 may be formed of a white organic light-emitting diode and sequentially disposed above there are an anode electrode AE, a color filter CF of a different color and an encapsulation layer ENC.

As shown in FIG. 1C, the transistor layer TFT is disposed above the substrate SUB; the cathode electrode CE is disposed above the transistor layer TFT; the organic light-emitting diode layer OLED3 is disposed above the cathode electrode CE; and the organic light-emitting diode layer OLED3 may be red (R), green (G) or blue (B). The organic light-emitting diode is configured and provided with an anode electrode AE, a color conversion layer CC, and an encapsulation layer ENC in this order.

However, the active matrix OLED display described above can only provide a display function. In order to provide a touch function, it is usually required to use an external touch sensing module, which not only increases the overall display, but also the thickness causes a drop in production yield, resulting in a significant increase in production costs.

As for micro light-emitting diode, it is a new type of display technology. As its name suggests, its size is smaller than that of the conventional light-emitting diode. It can usually be less than 100 um or even as small as 5 um, so it has the ability to realize the display panel with high pixels per inch (PPI).

In the process of the micro light-emitting diode display, red (R), green (G) and blue (B) inorganic LEDs can be separately formed on different epitaxial substrates, and then the specific transfer technique moves it from the epitaxial substrate to a drive circuit substrate (e.g., a glass substrate) and bonds it to a specific position on the drive circuit substrate. For example, as shown in FIG. 3A˜FIG. 3F, the micro light-emitting diode MLED can be sucked from the epitaxial substrate SUB1 by means of electromagnetic force, vacuum suction, van der Waals force, etc. through a special micro-clipper CP. Thereafter, the micro light-emitting diode MLED is transferred to the glass substrate SUB2 and bonded to a specific position on the glass substrate SUB2.

Since the inorganic light-emitting diode has high luminous efficiency characteristics, compared to the organic light-emitting diode, the micro light-emitting diode can emit the same or even higher brightness under a relatively small pixel light-emitting area. For example, the luminance of the organic light-emitting diode is up to about 1000 nits, and the luminance of the inorganic light-emitting diode can be as high as 106 nits, that is, the luminance of the inorganic light-emitting diode can be 1000 times that of the organic light-emitting diode.

In this case, the brightness of the micro light-emitting diode and the organic light-emitting diode can be equal when the size of the pixel light-emitting region of the micro light-emitting diode is only 25 um² (that is, 5 um *5 um), and the pixel illuminating region of the organic light-emitting diode is 25000 um² (that is, 158 um*158 um). Therefore, if the micro light-emitting diode display and the organic light-emitting diode display have the same pixel density and unit brightness, there will be a lot of free space without the light-emitting diode layer, the anode, the cathode and traces on the drive circuit substrate of the miniature light-emitting diode display, and the free space can be used to dispose other circuits and traces without affecting the original circuit layout of the display.

For example, all the pixels of the active matrix organic light-emitting diode display in FIG. 4A use a micro light-emitting diode MLED, whereas all the pixels in the active matrix OLED display in FIG. 4B are organic light-emitting diodes OLED. Due to the small size of the micro light-emitting diode MLED, the active matrix organic light-emitting diode display in FIG. 4A has a void area SP, which can be used to set up other circuits and lines rather than interfering with the original circuit layout of the display, compared to FIG. 4B.

From above, it can be found that if the passive matrix organic light-emitting diode display uses both organic light-emitting diode (OLED) and micro light-emitting diode (Micro LED) technology, as shown in FIG. 5, if the active matrix organic light-Emitting diode display is also using organic light-emitting diode (OLED) and micro light-emitting diode (micro LED) technology, as shown in FIG. 5, if a part of the pixels of the active matrix organic light-emitting diode display uses organic light-emitting diodes OLED, and the other part of the pixels uses micro light-emitting diodes MLED. As a result, because of the small size of the micro light-emitting diode MLED, the pixels using the micro light-emitting diode MLED have a void area SP, so they can be used to set up other circuits and lines without interfering with the original circuit layout of the display.

### SUMMARY OF THE INVENTION

Therefore, the invention provides an in-cell capacitive touch panel to solve the above-mentioned problems of the prior arts.

A preferred embodiment of the invention is an in-cell capacitive touch panel. In this embodiment, the in-cell capacitive touch panel applied to an active matrix light-emitting diode display is disclosed. The in-cell capacitive touch panel includes a plurality of pixels and at least one touch electrode. A laminated structure of each pixel includes a substrate, a first conductive layer, a second conductive layer, a third conductive layer, a fourth conductive layer, a transistor layer and a light-emitting diode layer. The substrate is disposed at one side of the pixel. The first conductive layer is disposed above the substrate and used to form a scan line. The transistor layer is disposed above the substrate. The second conductive layer is disposed above the substrate and used to form a date line. The third conductive layer is disposed above the transistor layer. The light-emitting diode layer is disposed above the third conductive layer. The fourth conductive layer is disposed above the light-emitting diode layer. The at least one touch electrode is disposed in a space among the first conductive layer˜the fourth conductive layer and the light-emitting diode layer.

In an embodiment, the laminated structure also includes an encapsulation layer and an insulating layer. The encapsulation layer is disposed at the other side of the pixel opposite to the substrate. The insulating layer is filled between the encapsulation layer and the substrate.

In an embodiment, the at least one touch electrode includes a first direction touch electrode and a second direction touch electrode. The first direction touch electrode and the second direction touch electrode are arranged along a first direction and a second direction respectively, and the first direction is perpendicular to the second direction.

In an embodiment, the first direction touch electrode is arranged in a space that the fourth conductive layer, the second conductive layer and the light-emitting diode layer are not disposed.

In an embodiment, the second direction touch electrode is arranged in a space that the first conductive layer and the light-emitting diode layer are not disposed.

In an embodiment, the third conductive layer forms a cathode and the fourth conductive layer forms an anode, or the third conductive layer forms the anode and the fourth conductive layer forms the cathode.

In an embodiment, the in-cell capacitive touch panel also includes a fifth conductive layer, coupled to the fourth conductive layer or the third conductive layer forming the anode in the plurality of pixels.

In an embodiment, the fifth conductive layer is arranged along the first direction in a space between the data lines formed of the second conductive layer, and does not overlap with the at least one touch electrode and the light-emitting diode layer.

In an embodiment, the fifth conductive layer is arranged along the second direction in a space between the scan lines formed of the first conductive layer, and does not overlap with the at least one touch electrode and the light-emitting diode layer.

In an embodiment, the at least one touch electrode is formed of the first conductive layer, the second conductive layer, the third conductive layer, the fourth conductive layer or the fifth conductive layer.

In one embodiment, the at least one touch electrode is formed of a sixth conductive layer, and the sixth conductive layer is different and insulated from the first conductive layer, the second conductive layer, the third conductive layer, the fourth conductive layer and the fifth conductive layer.

In an embodiment, the at least one touch electrode can be arranged side by side along a first direction in a space between the data lines formed of the second conductive layer.

In an embodiment, the at least one touch electrode can be arranged side by side along a second direction in a space between the scan lines formed of the first conductive layer.

In an embodiment, the first direction touch electrode and the second direction touch electrode are electrically connected through a via to form a mesh structure or a comb structure.

In an embodiment, when the at least one touch electrode is different and separated from the first conductive layer, the second conductive layer, the third conductive layer and the fourth conductive layer, the first direction touch electrode and the second direction touch electrode are formed of the same conductive layer to form a mesh structure or a comb structure.

In an embodiment, a circuit of the transistor layer includes a structure of two transistor and one capacitor (2T1C), a structure of four transistor and one capacitor (4T1C) or a structure of six transistor and one capacitor (6T1C).

In an embodiment, the plurality of pixels uses organic light-emitting diode (OLED) to form the light-emitting diode layer.

In an embodiment, the plurality of pixels uses micro light-emitting diode (micro LED) to form the light-emitting diode layer.

In an embodiment, a part of the plurality of pixels uses organic light-emitting diode to form the light-emitting diode layer, and the other part of the plurality of pixels uses micro light-emitting diode to form the light-emitting diode layer.

In an embodiment, the in-cell capacitive touch panel uses mutual-capacitive touch sensing technology or self-capacitive touch sensing technology.

In an embodiment, the light-emitting diode layer uses a top-emitting light-emitting diode structure, a bottom-emitting light-emitting diode structure or a double-sided penetrating light-emitting diode structure.

In an embodiment, a touch sensing mode and a display mode of the in-cell capacitive touch panel are driven in a time-dividing way, so that a touch sensing period and a display period of the in-cell capacitive touch panel do not overlap each other.

In an embodiment, when the in-cell capacitive touch panel operates in the touch sensing mode during a blanking interval out of the display period, the third conductive layer or the fourth conductive layer in the pixel is maintained at a fixed voltage.

In an embodiment, the blanking interval includes at least one of a vertical blanking interval, a horizontal blanking interval, and a long horizontal blanking interval, a time length of the long horizontal blanking interval is equal to or greater than a time length of the horizontal blanking interval, and the long horizontal blanking interval is obtained by redistributing the plurality of horizontal blanking intervals or the long horizontal blanking interval includes the vertical blanking interval.

In an embodiment, the touch sensing period and the display period of the in-cell capacitive touch panel are at least partially overlapped.

In an embodiment, when the in-cell capacitive touch panel is synchronized with a horizontal sync signal or a vertical sync signal or operates under the touch sensing mode in a blanking interval out of the display period, the third conductive layer or the fourth conductive layer of the pixel is maintained at a fixed voltage.

In an embodiment, the at least one touch electrode is formed of a conductive layer of a single direction and the conductive layer of the single direction is the first conductive layer, the second conductive layer, the third conductive layer, the fourth conductive layer, the fifth conductive layer or a sixth conductive layer, the six conductive layer is different and insulated from the first conductive layer, the second conductive layer, the third conductive layer, the fourth conductive layer and the fifth conductive layer.

In an embodiment, the at least one touch electrode can be arranged side by side along the first direction in the space between the data lines formed of the second conductive layer.

In an embodiment, the at least one touch electrode can be arranged side by side along the second direction in the space between the scan lines formed of the first conductive layer.

In an embodiment, the at least one touch electrode is disposed as a triangular or trapezoidal one-dimensional self-capacitive sensing electrode, and the touch position is determined by the self-capacitance sensed by the single self-capacitive sensing electrode or a ratio of the self-capacitances sensed by two adjacent self-capacitive sensing electrodes.

In an embodiment, a part of the at least one touch electrode is formed on the encapsulation layer, so that a distance between the part of the at least one touch electrode and the cathode or the anode is increased to reduce an interference between the touch and display.

In an embodiment, the in-cell capacitive touch panel also includes a touch pad and a touch controller. The touch pad is disposed on the encapsulation layer. The touch controller is directly disposed on the touch pad or disposed on the touch pad through a flexible printed circuit board.

In an embodiment, when the encapsulation layer uses a thin-film packaging process, the encapsulation layer can form a via or a slope descent structure, the at least one touch electrode disposed on the encapsulation layer can be connected to the substrate through touch electrode traces and connected to the flexible printed circuit board or the touch controller located on the substrate.

Compared to the prior art, the in-cell capacitive touch panel of the invention is suitable for an active matrix organic light-emitting diode display, and can effectively integrate display and touch functions, and the in-cell capacitive touch panel of the invention has the following advantages:

(1) The design of the touch sensing electrode and its traces is relatively simple, and can be applied to mutual-capacitive touch sensing technology or self-capacitive touch sensing technology.

(2) The original conductive layer in the panel can be used as touch electrodes to reduce the complexity of manufacturing process and the manufacturing cost.

(3) The overlapping area of the touch sensing electrode and the display driving electrode is relatively small, which can effectively reduce the RC loading of the panel and reduce noise.

(4) The touch sensing electrode system is disposed between pixels, so the display area of the pixel is not blocked, and the influence on the visibility of the panel can be reduced.

(5) Touch and display can be driven in a time-dividing way to improve the signal-to-noise ratio.

The advantage and spirit of the invention may be understood by the following detailed descriptions together with the appended drawings.

### BRIEF DESCRIPTION OF THE APPENDED DRAWINGS

FIG. 1 illustrates a schematic diagram of a conventional active matrix organic light-emitting diode display.

FIG. 2A˜FIG. 2C illustrate cross-sectional views of different laminated structures of the pixel od the active matrix organic light-emitting diode display respectively.

FIG. 3A˜FIG. 3F illustrate schematic diagrams of the process of transferring a micro light-emitting diode from an epitaxial substrate to a glass substrate through a special micro-clipper.

FIG. 4A illustrates a schematic diagram of the active matrix organic light-emitting diode display only using a micro light-emitting diode (Micro LED) technology.

FIG. 4B illustrates a schematic diagram of the active matrix organic light-emitting diode display only using an organic light-emitting diode (OLED) technology.

FIG. 5 illustrates a schematic diagram showing an active matrix type organic light-emitting diode display capable of simultaneously using an organic light-emitting diode (OLED) and a micro light-emitting diode (Micro LED) technology.

FIG. 6 illustrates a schematic diagram of an in-cell capacitive touch panel according to a preferred embodiment of the invention.

FIG. 7 illustrates a cross-sectional view of the laminated structure taken along the line AA′ in FIG. 6.

FIG. 8 illustrates a schematic diagram of coupling the anode in each pixel with a conductive layer of low impedance.

FIG. 9 illustrates a schematic diagram of the in-cell capacitive touch panel according to another preferred embodiment of the invention.

FIG. 10 illustrates a cross-sectional view of the laminated structure taken along the line AA′ in FIG. 9.

FIG. 11 illustrates a schematic diagram of the in-cell capacitive touch panel according to still another preferred embodiment of the invention.

FIG. 12 illustrates a cross-sectional view of the laminated structure taken along the section line AA′ in FIG. 11.

FIG. 13˜FIG. 15 illustrate timing diagrams of the vertical sync signal Vsync, the horizontal sync signal Hsync and the touch sensing drive signal STH of the in-cell capacitive touch panel in different embodiments.

FIG. 16 illustrates a schematic diagram of the in-cell capacitive touch panel according to still another preferred embodiment of the invention.

FIG. 17 illustrates a schematic diagram of the in-cell capacitive touch panel according to still another preferred embodiment of the invention.

FIG. 18 and FIG. 19 illustrate cross-sectional views of different laminated structures taken along the section line AA′ in FIG. 17.

FIG. 20 illustrates a schematic diagram of directly disposing the touch controller on the touch pad above the encapsulation layer.

FIG. 21 illustrates a schematic diagram of disposing the touch controller on the touch pad above the encapsulation layer through the flexible printed circuit board.

FIG. 22 illustrates a schematic diagram that when the encapsulation layer uses the thin-film packaging process, the touch electrodes arranged on the encapsulation layer can be connected to the substrate via a slope descent structure through the touch electrode traces and connected to the flexible printed circuit board located on the substrate.

FIG. 23 illustrates a schematic diagram that when the encapsulation layer uses the thin-film packaging process, the touch electrodes arranged on the encapsulation layer can be connected to the substrate via a slope descent structure through the touch electrode traces and connected to the touch controller located on the substrate.

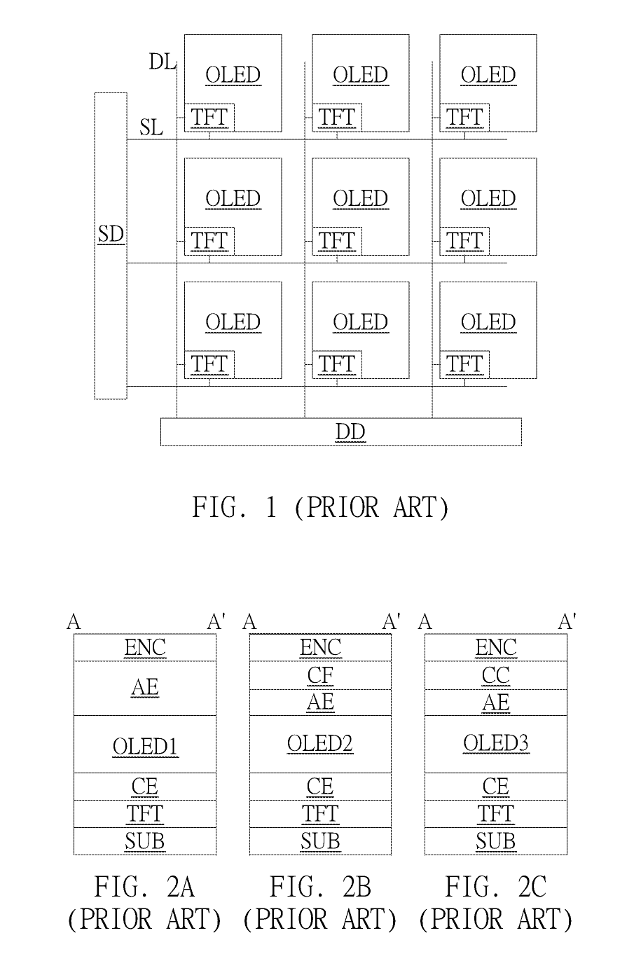

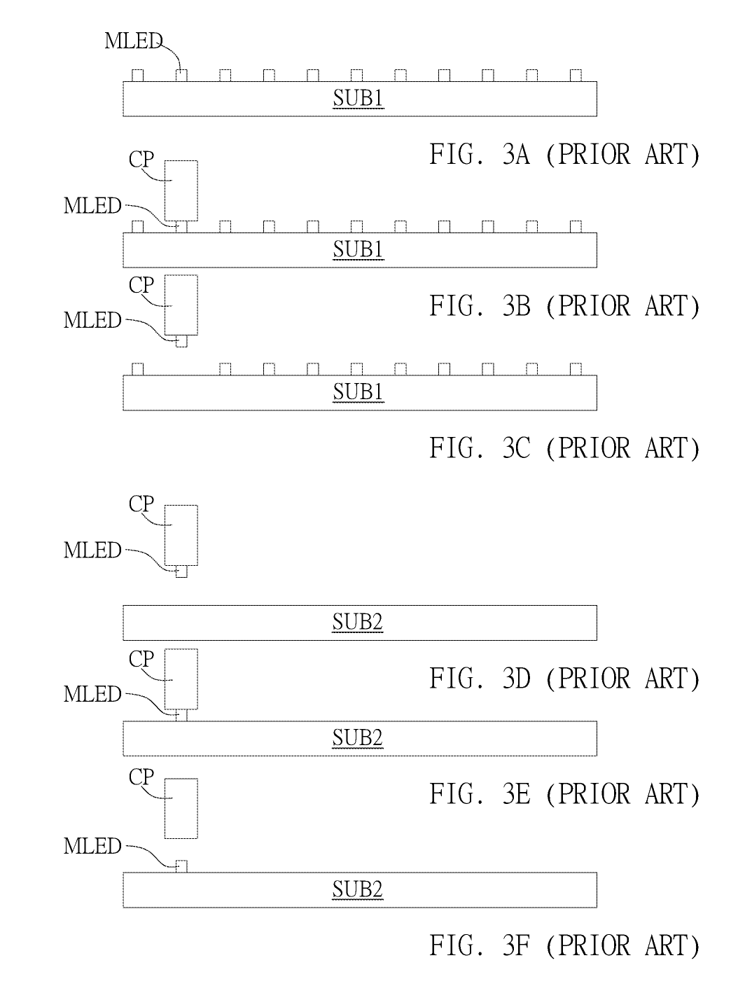

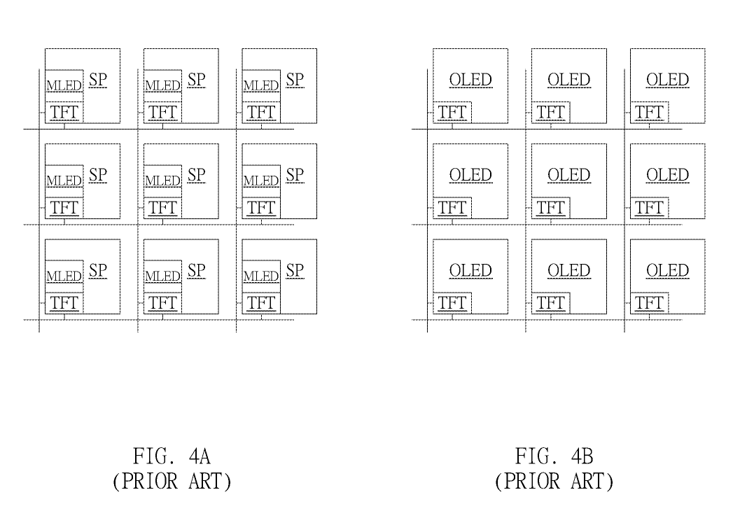

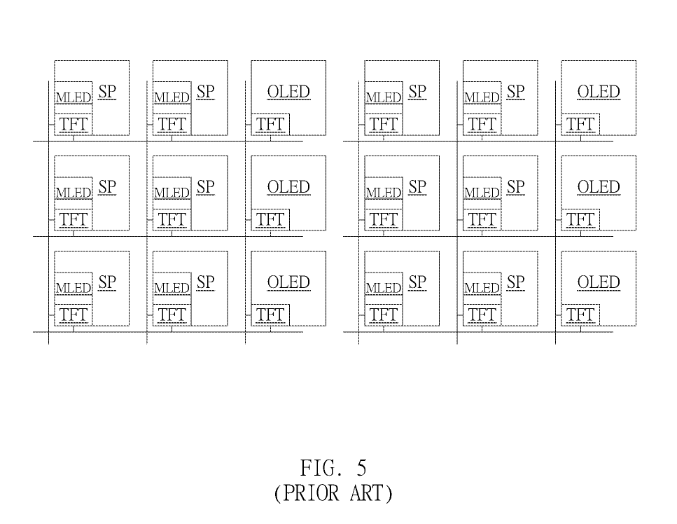

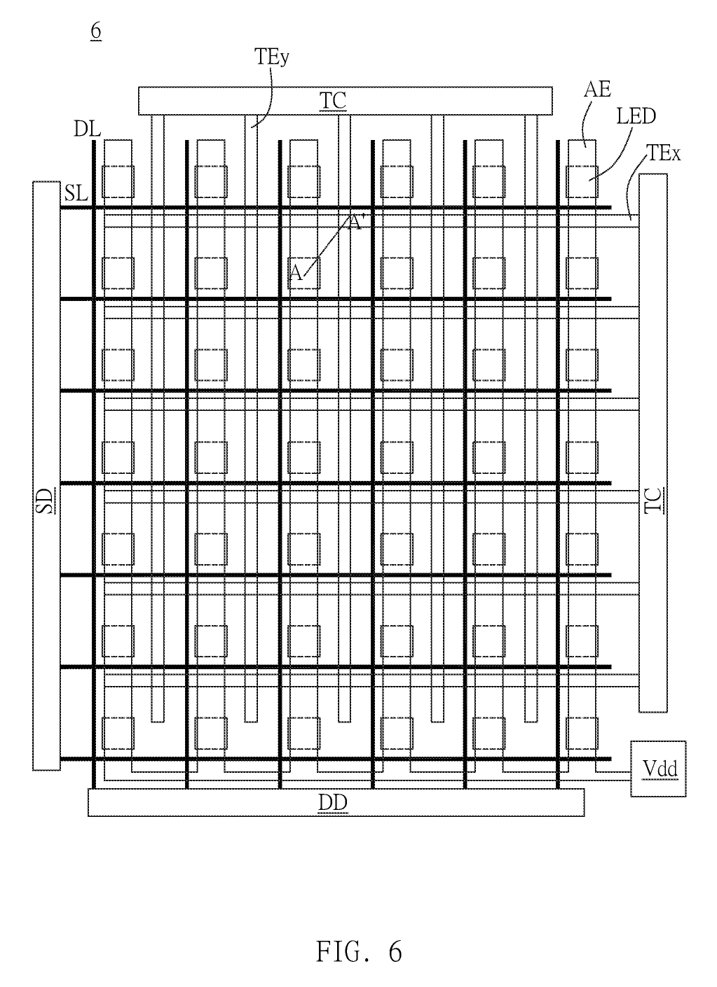

### DETAILED DESCRIPTION OF THE INVENTION

A preferred embodiment of the invention is an in-cell capacitive touch panel. In this embodiment, the in-cell capacitive touch panel is suitable for an active matrix light-emitting diode display using a mutual-capacitive touch technology or a self-capacitive touch technology. The detailed technical contents of the invention will be illustrated by different and better concrete embodiments respectively.

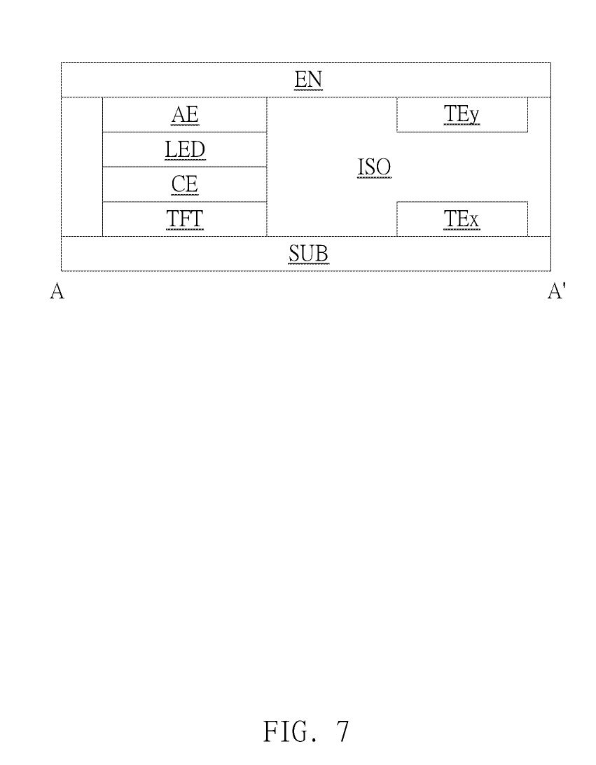

Please refer to FIG. 6 and FIG. 7. FIG. 6 illustrates a schematic diagram of an in-cell capacitive touch panel according to a preferred embodiment of the invention; FIG. 7 illustrates a cross-sectional view of the laminated structure taken along the line AA′ in FIG. 6.

As shown in FIG. 6 and FIG. 7, the active matrix light-emitting diode display 6 contains pixels and at least one touch electrode. The at least one touch electrode includes a first direction touch electrode TEy and a second direction touch electrode TEx. The first direction touch electrode TEy and the second direction touch electrode TEx are arranged along a first direction (e.g., Y direction) and a second direction (e.g., X direction), and the first direction is perpendicular to the second direction. Each pixel can include a scan line SL formed of a first conductive layer, a transistor layer TFT, a data line DL formed of a second conductive layer, a cathode CE formed of a third conductive layer, a light-emitting diode layer LED and an anode AE formed of a fourth conductive layer. The anode AE of each pixel can be patterned to form a first direction (e.g., Y direction) trace connected to an anode junction of each light-emitting diode layer LED. In addition, the active matrix LED display 6 also includes an encapsulation layer EN and an insulation layer ISO. The encapsulation layer EN is disposed on the other side of the pixel opposite to the substrate SUB. The insulation layer ISO is filled between the encapsulation layer EN and the substrate SUB.

In practical applications, traces of the first direction touch electrode TEy can be disposed in a space that the anode AE formed of the fourth conductive layer, the data line DL formed of the second conductive layer and the light-emitting diode layer LED are not disposed, but not limited to this. The second direction touch electrode TEx can be disposed in a space that the scan line SL formed of the first conductive layer and the light-emitting diode layer LED are not disposed, but not limited to this.

It should be stated that in addition to the embodiment of the third conductive layer to form the cathode CE and the fourth conductive layer to form the anode AE, the anode AE can be also formed of the third conductive layer and the cathode CE can be formed of the fourth conductive layer. In addition to the first direction (e.g., Y direction) traces, the anode AE of each pixel can also be patterned to form the second direction (e.g. X direction) traces connected to the anode connection point of each light-emitting diode layer LED. In general, the light-emitting diode layer LED can include an electronic transport layer (ETL), an electrical tunnel Transport layer (HTL), an electronic injection layer (EIL), an electrical hole injection layer (HIL) and a light-emitting layer (EL), but not limited to this.

Because the traces of the first direction touch electrode TEy and the second direction touch electrode TEx are disposed in the space that the conductive electrodes and the light-emitting diode layer LED are not disposed, it can reduce the power line of the touch electrode is affected by the interference of these components, and reduce the capacitance coupling between them in the meantime, to reduce the RC Loading and the noise interference.

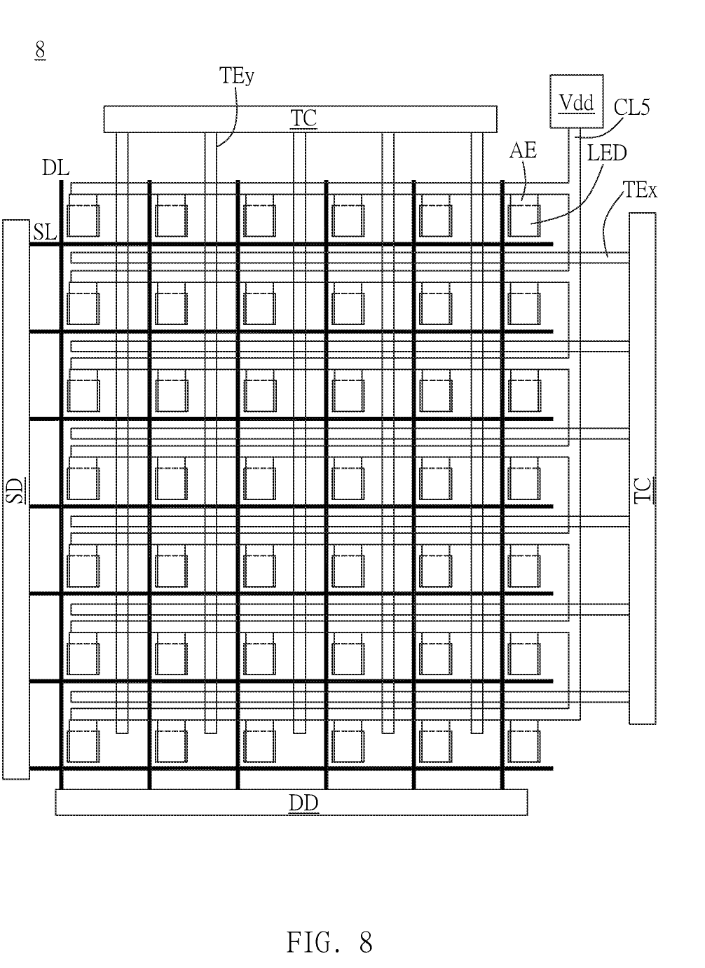

Please refer to FIG. 8. FIG. 8 illustrates a schematic diagram of coupling the anode in each pixel with a conductive layer of low impedance.

As shown in FIG. 8, due to the patterned anode layer may cause an increase in the resistance of the anode AE, resulting in uneven picture display condition. Therefore, the in-cell capacitive touch panel of the invention can include a fifth conductive layer CLS, to form anode connecting wires to be coupled to the anode AE in each pixel. The fifth conductive layer CL5 is a low impedance conductive layer, which can be arranged along the first direction (Y direction) in the space between the data lines DL formed of the second conductive layer, and not overlap the first direction touch electrode TEy or the light-emitting diode layer LED, to avoid increasing the touch-sensing RC loading or shielding the light emitted by the light-emitting diode layer LED.

Similarly, the fifth conductive layer CL5 can also be arranged along the second direction (X direction) in the space between the scan lines SL formed of the first conductive layer, and not overlap the second direction touch electrode TEx or the light-emitting diode layer LED, to avoid increasing the touch sensing RC loading or shielding the light emitted by the light-emitting diode layer LED.

In an embodiment, the at least one touch electrode can be formed of the first conductive layer forming the scan line SL, the second conductive layer forming the data line DL, the third conductive layer forming the cathode CE, the fourth conductive layer forming the anode AE or the fifth conductive layer CL5 forming the anode wire.

In another embodiment, the at least one touch electrode can be formed of a sixth conductive layer, and the sixth conductive layer is different and insulated from the first conductive layer forming the scan line SL, the second conductive layer forming the data line DL, the third conductive layer forming the cathode CE, the fourth conductive layer forming the anode AE or the fifth conductive layer CL5 forming the anode wire.

In fact, the at least one touch electrode can be disposed side by side along the first direction (e.g., Y direction) in a space between the data lines DL formed of the second conductive layer, or along the second direction (e.g., X direction) in a space between the scan lines SL formed of the first conductive layer.

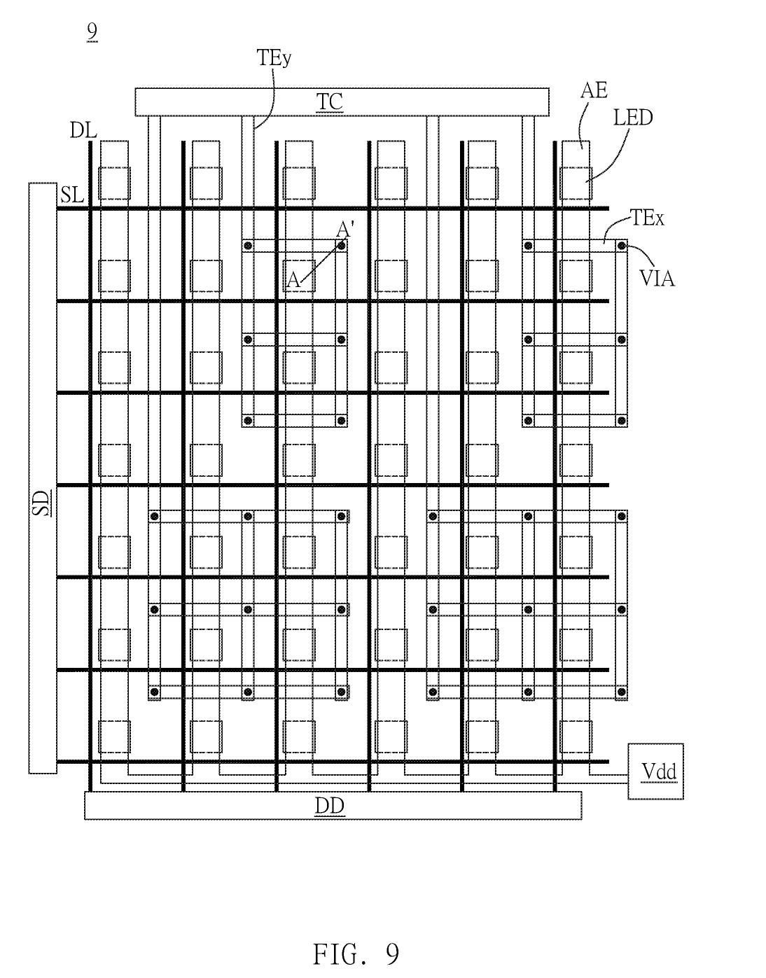

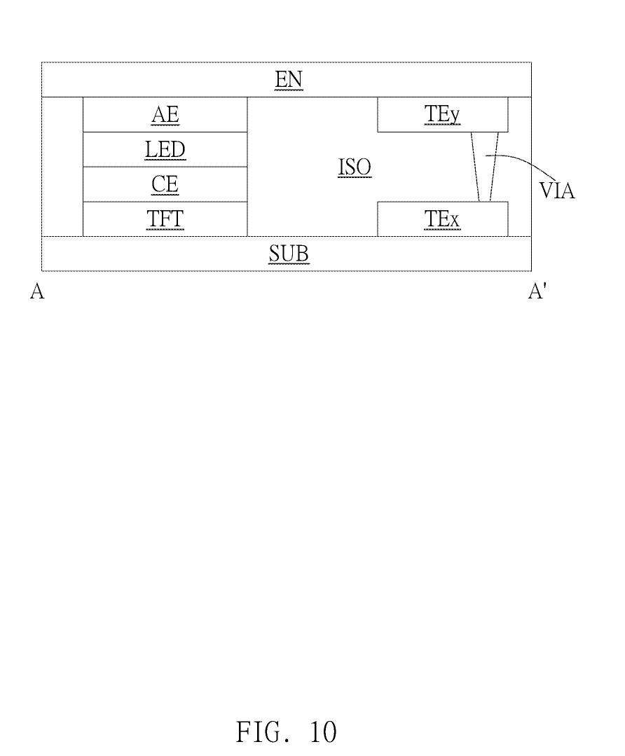

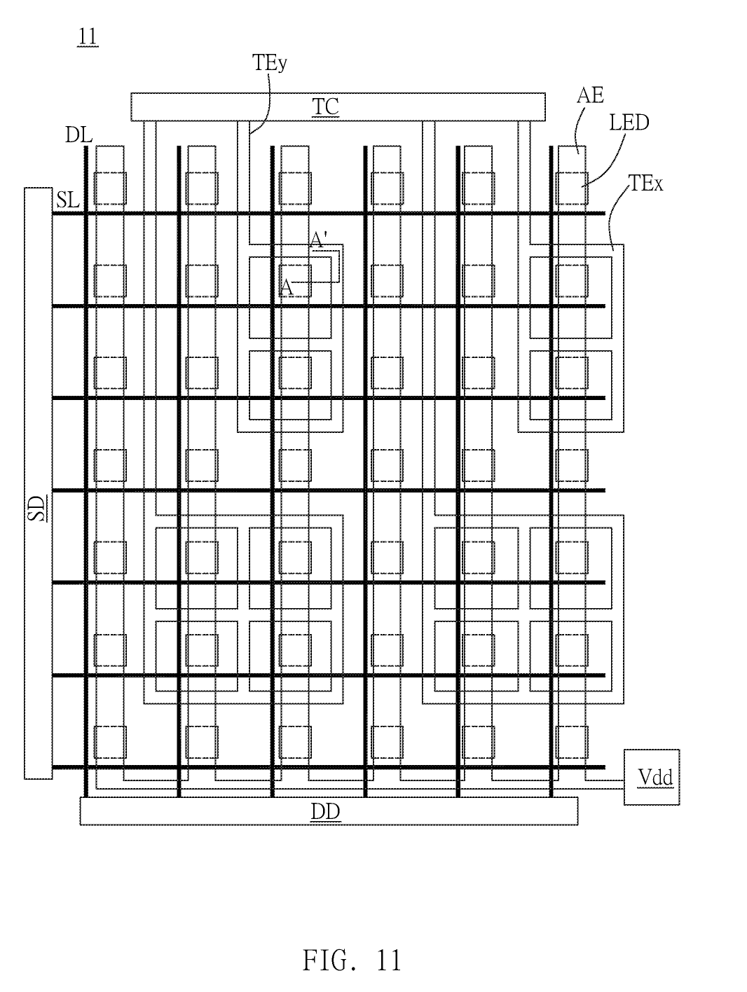

Then, as shown in FIG. 9 and FIG. 10, the first direction touch electrode TEy and the second direction touch electrode TEx can be electrically connected through the via to form a mesh structure or a comb structure, but not limited to this.

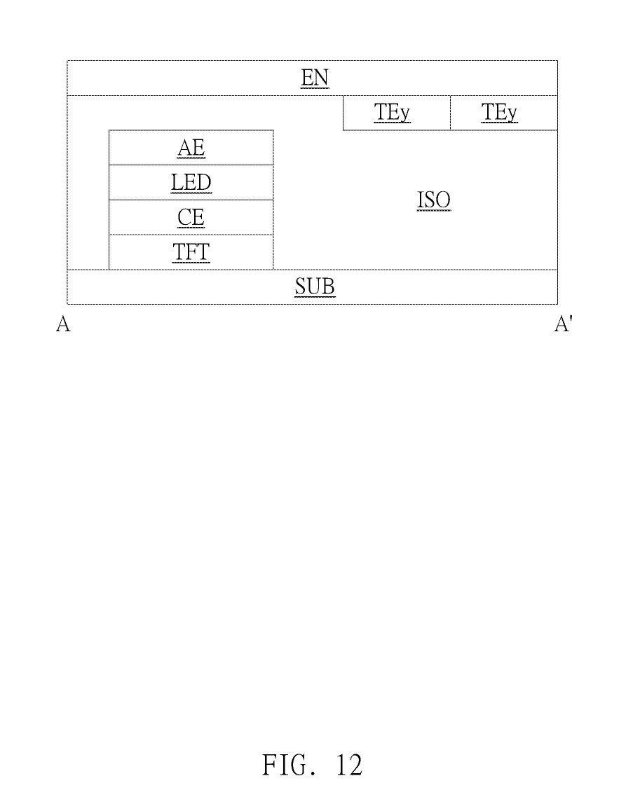

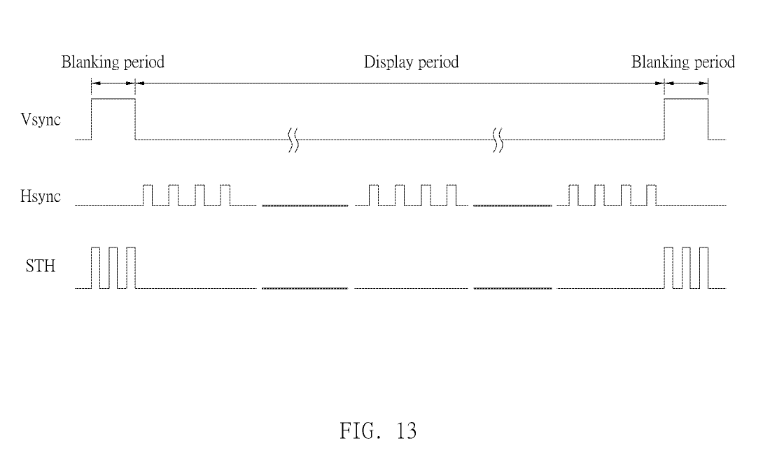

In addition, as shown in FIG. 11 and FIG. 12, when the at least one touch electrode is different from the first conductive layer forming the scan line SL, the second conductive layer forming the data line DL, the third conductive layer forming the cathode CE and the fourth conductive layer forming the anode AE and separated from each other by the insulation layer, the first direction touch electrode TEy and the second direction touch electrode TEx can be formed of the same conductive layer to form a mesh structure or a comb structure, the electrical connection through the via is unnecessary.

In practical applications, a circuit of the transistor layer includes a structure of two transistor and one capacitor (2T1C), a structure of four transistor and one capacitor (4T1C) or a structure of six transistor and one capacitor (6T1C), but not to this limit. The pixels can all use organic light-emitting diode (OLED) to form the light-emitting diode layer LED, all use micro LED to form the light-emitting diode layer LED, or a part of the pixels using an organic light-emitting diode to form the light-emitting diode layer LED and another part of the pixels using a micro light-emitting diode to form the light-emitting diode layer LED. In addition, the light-emitting diode layer LEDs can use a top-emitting light-emitting diode structure, a bottom-emitting light-emitting diode structure or a double-sided light-emitting diode structure, and there are no specific limitations.

It should be stated that the touch sensing mode and the display mode of the in-cell capacitive touch panel in the invention can be driven in a time-dividing way, resulting in the touch sensing period and the display period of the in-cell capacitive touch panel do not overlap, but not limited to this.

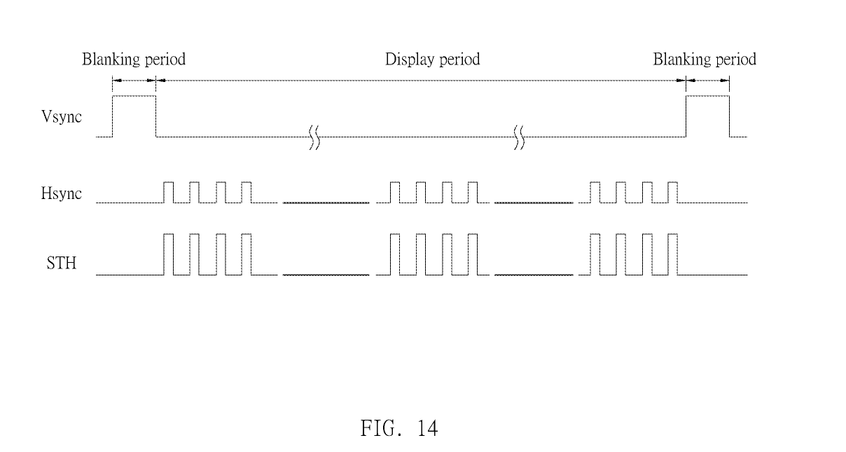

Next, please refer to FIG. 13˜FIG. 15. FIG. 13˜FIG. 15 illustrate timing diagrams of the vertical sync signal Vsync, the horizontal sync signal Hsync and the touch sensing drive signal STH of the in-cell capacitive touch panel in different embodiments.

In an embodiment, the in-cell capacitive touch panel of the invention can operate in the touch sensing mode in a blanking interval out of the display period. In fact, the blanking interval can include at least one of a vertical blanking interval, a horizontal blanking interval and a long horizontal blanking interval. Wherein, the time length of the long horizontal blanking interval is equal to or longer than the time length of the horizontal blanking interval; the long horizontal blanking interval is obtained by redistributing the plurality of horizontal blanking intervals or the long horizontal blanking interval includes the vertical blanking interval.

For example, as shown in FIG. 13, the touch sensing driving signal STH is operated in the blanking interval of the vertical synchronization signal Vsync. At this time, the cathode electrode CE formed of the third conductive layer or the anode electrode AE formed of the fourth conductive layer can be maintained at a fixed voltage, but not limited to this.

In another embodiment, the touch sensing of the in-cell capacitive touch panel in the invention can also be performed in the display interval of the display period, and it can be synchronized with the horizontal synchronization signal Hsync or the vertical synchronization signal Vsync. For example, as shown in FIG. 14, the touch sensing driving signal STH is operated in the display interval of the display period, and the touch sensing driving signal STH is synchronized with the horizontal synchronization signal Hsync. At this time, the cathode electrode CE formed of the third conductive layer or the anode electrode AE formed of the fourth conductive layer can be maintained at a fixed voltage, but not limited to this.

In another embodiment, the touch sensing of the in-cell capacitive touch panel of the invention can be also operated in the touch sensing mode in a blanking interval of the display period. For example, as shown in FIG. 15, the touch sensing driving signal STH is not synchronized with the horizontal synchronization signal Hsync or the vertical synchronization signal Vsync, but it is operated by the long horizontal blanking interval LHB of the horizontal synchronization signal Hsync during the display period. At this time, the cathode electrode CE formed of the third conductive layer or the anode electrode AE formed of the fourth conductive layer can be maintained at a fixed voltage, but not limited to this.

In a practical application, the touch sensing period of the in-cell capacitive touch panel of the invention can at least partially overlap with the display interval of the display period, as shown in FIG. 14 and FIG. 15.

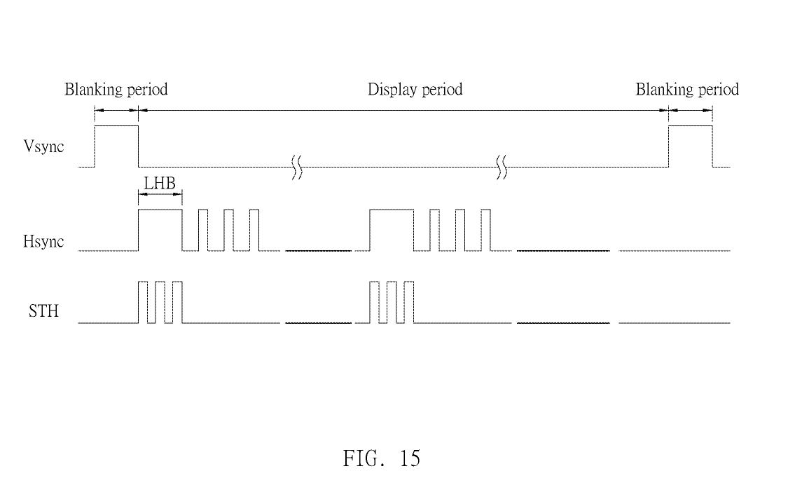

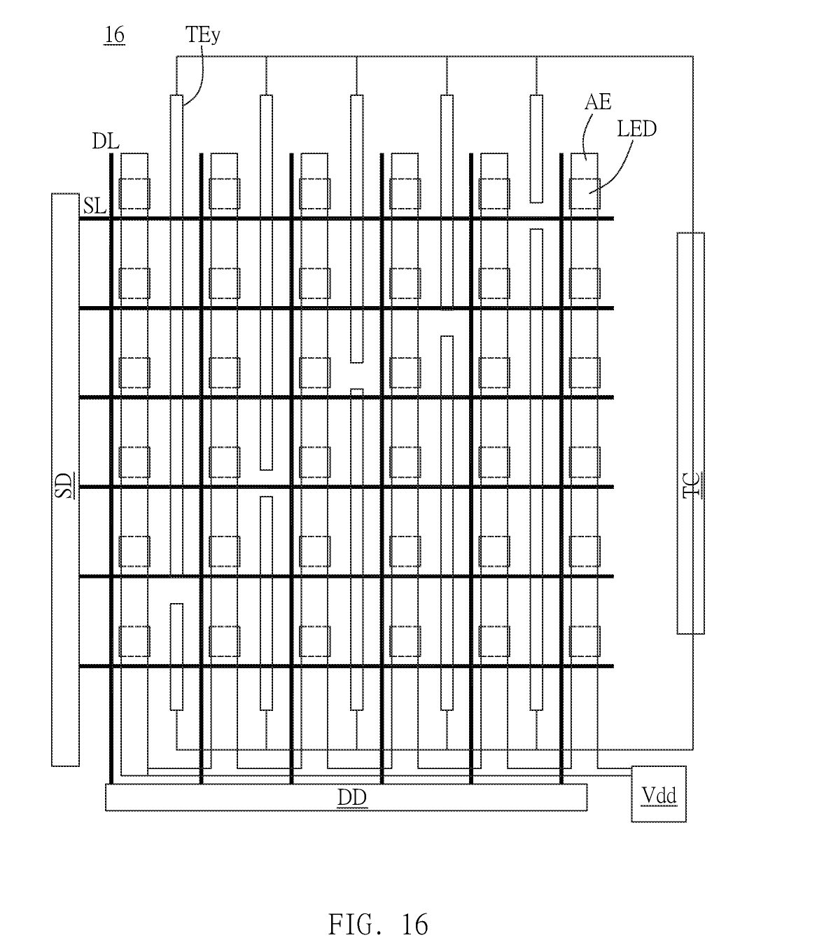

Then, as shown in FIG. 16, the touch electrode of the in-cell capacitive touch panel 16 can be formed by a conductive layer of a single direction (e.g., the first-direction touch electrode TEy) and the conductive layer can be formed by the first conductive layer forming the scan line SL, the second conductive layer forming the data line DL, the third conductive layer forming the cathode CE, the fourth conductive layer forming the anode AE, the fifth conductive layer CL5 forming the anode wire or the sixth conductive layer different from the first conductive layer to the conductive layer and insulated from each other.

In addition, the touch electrode formed by the conductive layer of the single direction can be arranged side by side along the first direction (e.g., Y direction) in the space between the data lines DL formed by the second conductive layer, for example, the first direction touch electrode TEy, or the touch electrode formed by the conductive layer of the single direction can be arranged side by side along the second direction (e.g., X direction) in the space between the scan lines SL formed by the first conductive layer, for example, the second direction touch electrode TEx.

In practical applications, the touch electrode formed by the conductive layer of the single direction (e.g., the first direction touch electrode TEy or the second direction touch electrode TEx) can be arranged as a triangular or trapezoidal one-dimensional self-capacitive sensing electrode. The touch position can be determined by the self-capacitance sensed by a single self-capacitive sensing electrode or a ratio of self-capacitances sensed by the adjacent two self-capacitance sensing electrodes, but not limited to this.

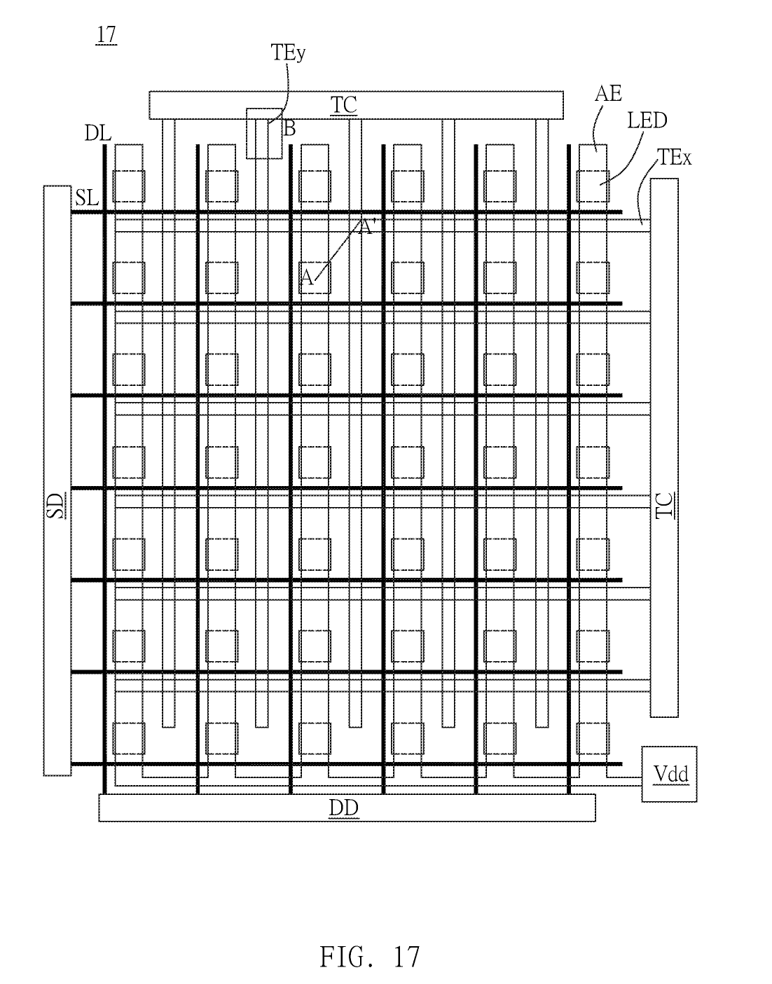

As shown in FIG. 17 to FIG. 19, a part of the touch electrodes (e.g., the first-direction touch electrode TEy or the second-direction touch electrode TEx) can be formed on the encapsulation layer EN, so that the distance between the part of the touch electrodes and the cathode CE or the anode AE will increase to reduce the interference between touch and display. Another part of the touch electrodes not formed on the encapsulation layer EN can be disposed above the substrate SUB or under the encapsulation layer EN. A connection area B of the part of the touch electrodes (e.g., the first direction touch electrode TEy) and the Touch controller TC formed on the encapsulation layer EN is shown in FIG. 17.

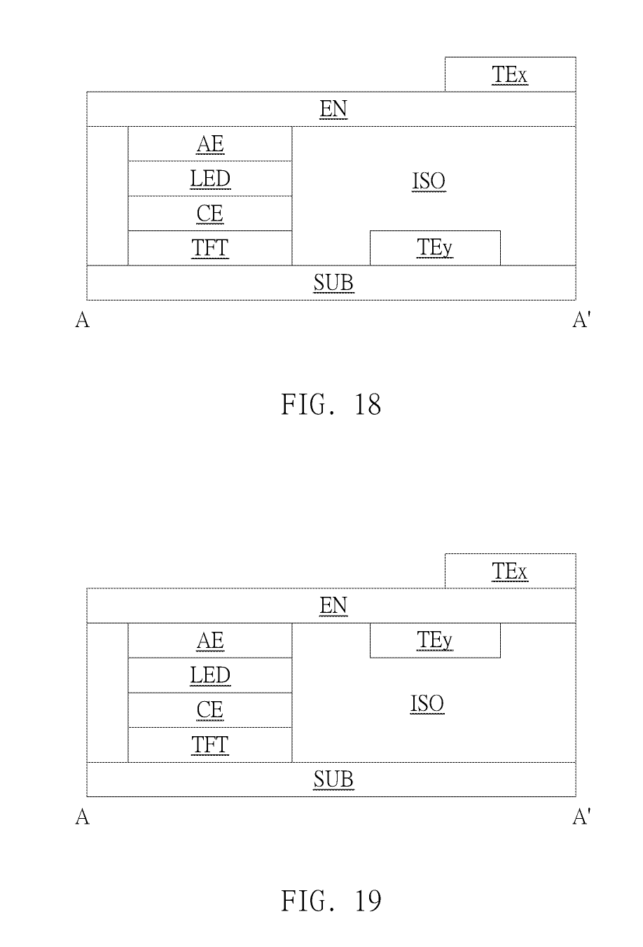

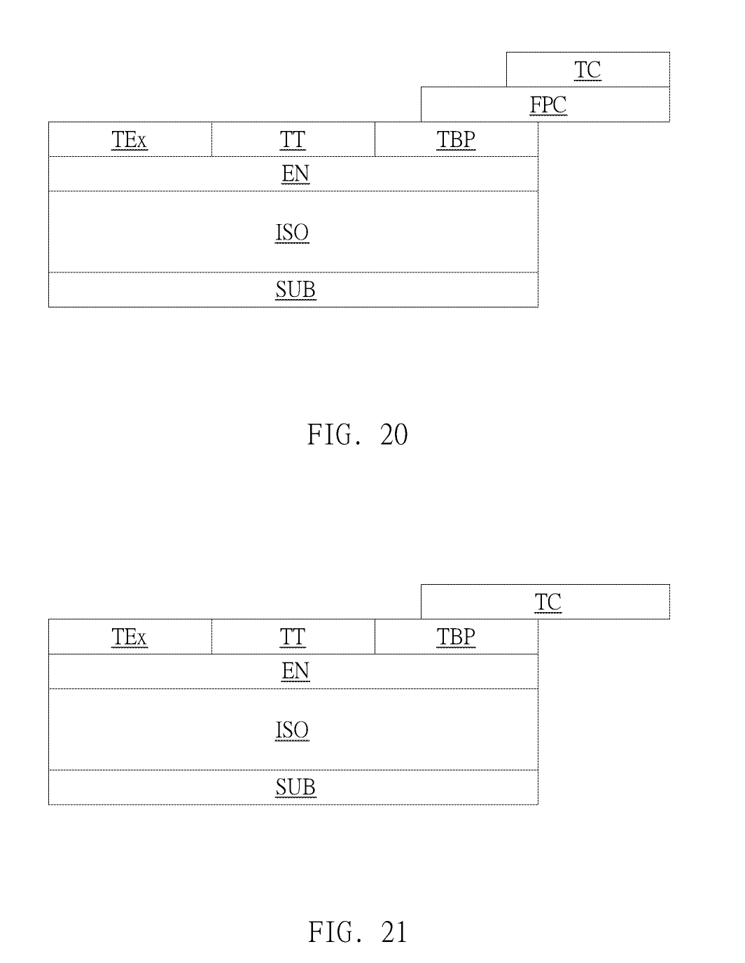

Then, as shown in FIG. 20 and FIG. 21, the in-cell capacitive touch panel can also include a touch pad TBP and a touch controller TC. The touch pad TBP is arranged on the encapsulation layer EN. The touch controller TC can be directly disposed on the touch pad TBP or disposed on the touch pad TBP through the flexible printed circuit board.

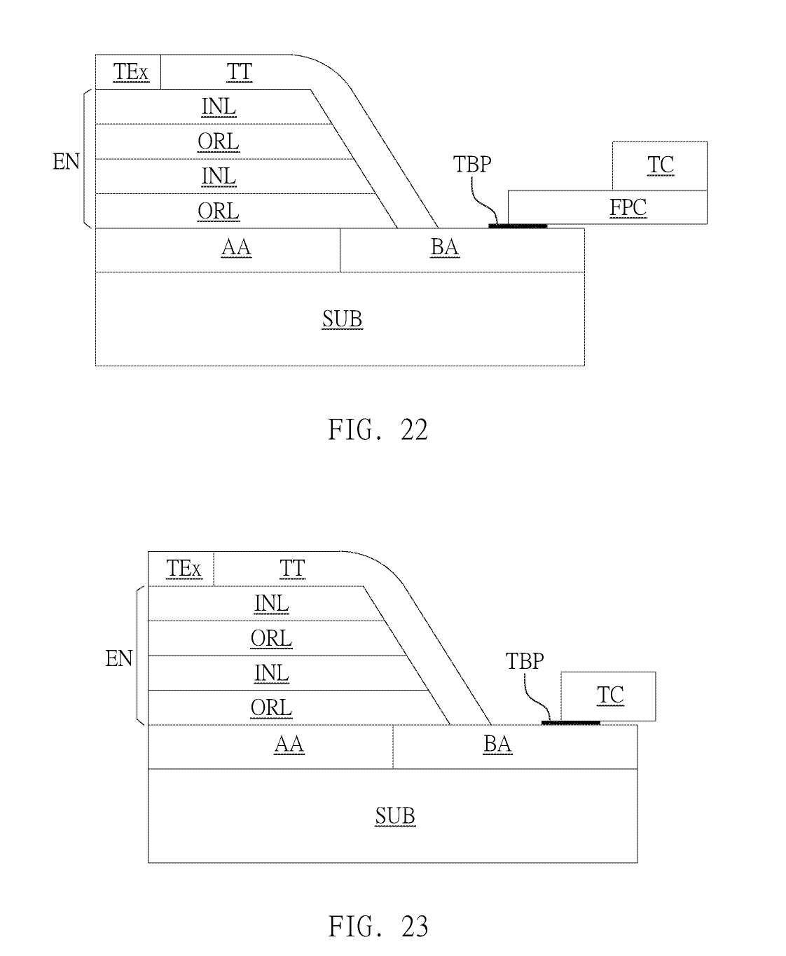

In addition, as shown in FIG. 22 and FIG. 23, when the encapsulation layer EN uses a thin-film packaging process, the encapsulation layer EN can include a multi-layered structure formed of staggered inorganic layers INL and organic layers ORL, and the encapsulation layer EN can form through hole or slope descent structure, so that the touch electrode TEx disposed above the encapsulation layer EN can be connected to the display border area BA of the substrate SUB through the touch electrode traces TT and is connected to the flexible printed circuit board FPC or the touch controller TC, but not limited to this.

Compared to the prior art, the in-cell capacitive touch panel of the invention is suitable for an active matrix organic light-emitting diode display, and can effectively integrate display and touch functions, and the in-cell capacitive touch panel of the invention has the following advantages:

(1) The design of the touch sensing electrode and its traces is relatively simple, and can be applied to mutual-capacitive touch sensing technology or self-capacitive touch sensing technology.

(2) The original conductive layer in the panel can be used as touch electrodes to reduce the complexity of manufacturing process and the manufacturing cost.

(3) The overlapping area of the touch sensing electrode and the display driving electrode is relatively small, which can effectively reduce the RC loading of the panel and reduce noise.

(4) The touch sensing electrode system is disposed between pixels, so the display area of the pixel is not blocked, and the influence on the visibility of the panel can be reduced.

(5) Touch and display can be driven in a time-dividing way to improve the signal-to-noise ratio.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An in-cell capacitive touch panel, applied to an active matrix light-emitting diode display, the in-cell capacitive touch panel comprising:
a plurality of pixels, a laminated structure of a pixel of the plurality of pixels comprising;
a substrate, disposed at one side of the pixel;
a first conductive layer, disposed above the substrate and used to form a scan line;
a transistor layer, disposed above the substrate;
a second conductive layer, disposed above the substrate and used to form a date line;
a third conductive layer, disposed above the transistor layer; and
a light-emitting diode layer, disposed above the third conductive layer; and
a fourth conductive layer, disposed above the light-emitting diode layer; and
at least one touch electrode, disposed in a space that the first conductive layer, the second conductive layer, the third conductive layer, the fourth conductive layer and the light-emitting diode layer are not disposed.

2. The in-cell capacitive touch panel of claim 1, wherein the laminated structure further comprises:
an encapsulation layer, disposed on another side of the pixel opposite to the substrate; and
an insulating layer, filled between the encapsulation layer and the substrate.

3. The in-cell capacitive touch panel of claim 2, wherein the at least one touch electrode comprises a first direction touch electrode and a second direction touch electrode, the first direction touch electrode and the second direction touch electrode are arranged along a first direction and a second direction respectively, and the first direction is perpendicular to the second direction.

4. The in-cell capacitive touch panel of claim 3, wherein the first direction touch electrode is arranged in a space that the fourth conductive layer, the second conductive layer and the light-emitting diode layer are not disposed.

5. The in-cell capacitive touch panel of claim 3, wherein the second direction touch electrode is arranged in a space that the first conductive layer and the light-emitting diode layer are not disposed.

6. The in-cell capacitive touch panel of claim 1, wherein the third conductive layer forms a cathode and the fourth conductive layer forms an anode, or the third conductive layer forms the anode and the fourth conductive layer forms the cathode.

7. The in-cell capacitive touch panel of claim 1, further comprising:
a fifth conductive layer, coupled to the fourth conductive layer or the third conductive layer forming the anode in the plurality of pixels.

8. The in-cell capacitive touch panel of claim 7, wherein the fifth conductive layer is arranged along the first direction in a space between the data lines formed of the second conductive layer, and does not overlap with the at least one touch electrode and the light-emitting diode layer.

9. The in-cell capacitive touch panel of claim 7, wherein the fifth conductive layer is arranged along the second direction in a space between the scan lines formed of the first conductive layer, and does not overlap with the at least one touch electrode and the light-emitting diode layer.

10. The in-cell capacitive touch panel of claim 7, wherein the at least one touch electrode is formed of the first conductive layer, the second conductive layer, the third conductive layer, the fourth conductive layer or the fifth conductive layer.

11. The in-cell capacitive touch panel of claim 7, wherein the at least one touch electrode is formed of a sixth conductive layer, and the sixth conductive layer is different and insulated from the first conductive layer, the second conductive layer, the third conductive layer, the fourth conductive layer and the fifth conductive layer.

12. The in-cell capacitive touch panel of claim 1, wherein the at least one touch electrode can be arranged side by side along a first direction in a space between the data lines formed of the second conductive layer.

13. The in-cell capacitive touch panel of claim 1, wherein the at least one touch electrode can be arranged side by side along a second direction in a space between the scan lines formed of the first conductive layer.

14. The in-cell capacitive touch panel of claim 3, wherein the first direction touch electrode and the second direction touch electrode are electrically connected through a via to form a mesh structure or a comb structure.

15. The in-cell capacitive touch panel of claim 3, wherein when the at least one touch electrode is different and separated from the first conductive layer, the second conductive layer, the third conductive layer and the fourth conductive layer, the first direction touch electrode and the second direction touch electrode are formed of the same conductive layer to form a mesh structure or a comb structure.

16. The in-cell capacitive touch panel of claim 1, wherein a circuit of the transistor layer comprises a structure of two transistor and one capacitor (2T1C), a structure of four transistor and one capacitor (4T1C) or a structure of six transistor and one capacitor (6T1C).

17. The in-cell capacitive touch panel of claim 1, wherein the plurality of pixels uses organic light-emitting diode (OLED) to form the light-emitting diode layer.

18. The in-cell capacitive touch panel of claim 1, wherein the plurality of pixels uses micro light-emitting diode (micro LED) to form the light-emitting diode layer.

19. The in-cell capacitive touch panel of claim 1, wherein a part of the plurality of pixels uses organic light-emitting diode to form the light-emitting diode layer, and the other part of the plurality of pixels uses micro light-emitting diode to form the light-emitting diode layer.

20. The in-cell capacitive touch panel of claim 1, wherein the in-cell capacitive touch panel uses mutual-capacitive touch sensing technology or self-capacitive touch sensing technology.

21. The in-cell capacitive touch panel of claim 1, wherein the light-emitting diode layer uses a top-emitting light-emitting diode structure, a bottom-emitting light-emitting diode structure or a double-sided penetrating light-emitting diode structure.

22. The in-cell capacitive touch panel of claim 1, wherein a touch sensing mode and a display mode of the in-cell capacitive touch panel are driven in a time-dividing way, so that a touch sensing period and a display period of the in-cell capacitive touch panel do not overlap each other.

23. The in-cell capacitive touch panel of claim 22, wherein when the in-cell capacitive touch panel operates in the touch sensing mode during a blanking interval out of the display period, the third conductive layer or the fourth conductive layer in the pixel is maintained at a fixed voltage.

24. The in-cell capacitive touch panel of claim 22, wherein the blanking interval comprises at least one of a vertical blanking interval, a horizontal blanking interval, and a long horizontal blanking interval, a time length of the long horizontal blanking interval is equal to or greater than a time length of the horizontal blanking interval, and the long horizontal blanking interval is obtained by redistributing the plurality of horizontal blanking intervals or the long horizontal blanking interval comprises the vertical blanking interval.

25. The in-cell capacitive touch panel of claim 1, wherein the touch sensing period and the display period of the in-cell capacitive touch panel are at least partially overlapped.

26. The in-cell capacitive touch panel of claim 25, wherein when the in-cell capacitive touch panel is synchronized with a horizontal sync signal or a vertical sync signal or operates under the touch sensing mode in a blanking interval out of the display period, the third conductive layer or the fourth conductive layer of the pixel is maintained at a fixed voltage.

27. The in-cell capacitive touch panel of claim 25, wherein the blanking interval comprises at least one of a vertical blanking interval, a horizontal blanking interval, and a long horizontal blanking interval, a time length of the long horizontal blanking interval is equal to or greater than a time length of the horizontal blanking interval, and the long horizontal blanking interval is obtained by redistributing the plurality of horizontal blanking intervals or the long horizontal blanking interval comprises the vertical blanking interval.

28. The in-cell capacitive touch panel of claim 1, wherein the at least one touch electrode is formed of a conductive layer of a single direction and the conductive layer of the single direction is the first conductive layer, the second conductive layer, the third conductive layer, the fourth conductive layer, the fifth conductive layer or a sixth conductive layer, the six conductive layer is different and insulated from the first conductive layer, the second conductive layer, the third conductive layer, the fourth conductive layer and the fifth conductive layer.

29. The in-cell capacitive touch panel of claim 28, wherein the at least one touch electrode can be arranged side by side along the first direction in a space between the data lines formed of the second conductive layer.

30. The in-cell capacitive touch panel of claim 28, wherein the at least one touch electrode can be arranged side by side along the second direction in a space between the scan lines formed of the first conductive layer.

31. The in-cell capacitive touch panel of claim 28, wherein the at least one touch electrode is disposed as a triangular or trapezoidal one-dimensional self-capacitive sensing electrode, and the touch position is determined by the self-capacitance sensed by the single self-capacitive sensing electrode or a ratio of the self-capacitances sensed by two adjacent self-capacitive sensing electrodes.

32. The in-cell capacitive touch panel of claim 2, wherein a part of the at least one touch electrode is formed on the encapsulation layer, so that a distance between the part of the at least one touch electrode and the cathode or the anode is increased to reduce an interference between the touch and display.

33. The in-cell capacitive touch panel of claim 2, further comprising:
a touch pad disposed on the encapsulation layer; and
a touch controller, directly disposed on the touch pad or disposed on the touch pad through a flexible printed circuit board.

34. The in-cell capacitive touch panel of claim 2, wherein when the encapsulation layer uses a thin-film packaging process, the encapsulation layer can form a via or a slope descent structure, the at least one touch electrode disposed on the encapsulation layer can be connected to the substrate through touch electrode traces and connected to the flexible printed circuit board or the touch controller located on the substrate.
